(19) United States
(12) Patent Application Publication
(10) Pub. No.: US 2015/0364627 A1
(43) Pub. Date: Dec. 17, 2015

(54) SOLAR CELL, SOLAR CELL MODULE, AND PRODUCTION METHOD FOR SOLAR CELL

(71) Applicant: Panasonic Intellectual Property Management Co., Ltd., Osaka (JP)

(72) Inventor: Tomoki NARITA, Osaka (JP)

(21) Appl. No.: 14/834,711

(22) Filed: Aug. 25, 2015

Related U.S. Application Data
(63) Continuation of application No. PCT/JP2013/082412, filed on Dec. 3, 2013.

(30) Foreign Application Priority Data
Feb. 26, 2013 (JP) 2013-035465

(51) Int. Cl. H01L 31/0224; H01L 31/054; H01L 31/18; H01L 31/048

(52) U.S. Cl. CPC H01L 31/022475; H01L 31/022433; H01L 31/048; H01L 31/0547; H01L 31/1884

(57) ABSTRACT

A solar cell is disclosed that comprises a photoelectric conversion body with first and second principle surfaces, a first transparent conductive oxide layer on the first principle surface, and comprising indium oxide containing a metal dopant, a first electrode on the first transparent conductive oxide layer, a second transparent conductive oxide layer on the second principle surface, and comprising indium oxide not containing a metal dopant but containing hydrogen and a second electrode on the second transparent conductive oxide layer.

### CROSS REFERENCE TO RELATED APPLICATIONS

This application is a continuation application of International Application No. PCT/JP2013/082412, filed on Dec. 3, 2013, entitled “SOLAR CELL, SOLAR CELL MODULE, AND PRODUCTION METHOD FOR SOLAR CELL”, which claims priority based on the Article 8 of Patent Cooperation Treaty from prior Japanese Patent Application No. 2013-035465, filed on Feb. 26, 2013, the entire contents of which are incorporated herein by reference.

### BACKGROUND

The disclosure relates to a solar cell, a solar cell module and a method of manufacturing a solar cell.

In a solar cell module, solar cells are provided inside a bonding layer filled between a light-receiving surface member and a rear surface member. For example, Japanese Patent Application Publication No. 2006-36874 (Patent Document 1) discloses improving a light utilization efficiency by adding pigment made of titanium oxide to a portion of the bonding layer located between the solar cells and the rear surface member.

There is a demand to improve output characteristics of a solar cell module.

### SUMMARY

An embodiment of a solar cell comprises a photoelectric conversion body with first and second principle surfaces, a first transparent conductive oxide layer on the first principle surface, and comprising indium oxide containing a metal dopant, a first electrode on the first transparent conductive oxide layer, a second transparent conductive oxide layer on the second principle surface, and comprising indium oxide not containing a metal dopant but containing hydrogen, and a second electrode on the second transparent conductive oxide layer.

An embodiment of a solar cell module comprises a sealant, and a solar cell arranged inside of the sealant, wherein the solar cell includes a photoelectric conversion body with first and second principle surfaces, a first transparent conductive oxide layer on the first principle surface, and comprising indium oxide containing a metal dopant, a first electrode on the first transparent conductive oxide layer, a second transparent conductive oxide layer on the second principle surface, and comprising indium oxide not containing a metal dopant but containing hydrogen, and a second electrode on the second transparent conductive oxide layer; and a reflection member that reflects more infrared light than the second principle surface to a rear surface side of the solar cell module.

An embodiment of method of manufacturing a solar cell that comprises forming a second transparent conductive oxide layer on a second principle surface of a photoelectric conversion body with a first principle surface and the second principle surface, the second transparent conductive oxide layer made of indium oxide not containing a metal dopant but containing hydrogen, and forming a first transparent conductive oxide layer on the first principle surface, the first transparent conductive oxide layer made of indium oxide containing a metal dopant, and forming a first electrode on the first transparent conductive oxide layer and forming a second electrode on the second transparent conductive oxide layer.

### BRIEF DESCRIPTION OF THE DRAWINGS

FIG. 1 is a schematic cross sectional view of a solar cell module according to a first embodiment.

FIG. 2 is a schematic cross sectional view of the solar cell module according to the first embodiment.

FIG. 3 is a schematic cross sectional view of a solar cell module according to a second embodiment.

### DETAILED DESCRIPTION

Hereinafter, examples of preferred embodiments are described. It should be noted that the embodiments described below are just for illustrative purposes. The invention is not limited to the embodiments below.

In addition, in the drawings referenced in the embodiments and the like, members having substantially the same function are denoted by the same reference numeral. Further, the drawings referenced in the embodiments and the like are schematic drawings. Hence, dimensional ratios and the like of objects depicted in the drawings may be different from the actual dimensional ratios and the like of the objects. The dimensional ratios and the like of the objects in the drawings may be different among the drawings as well. Specific dimensional ratios and the like of the objects should be determined in consideration of the following description.

### First Embodiment

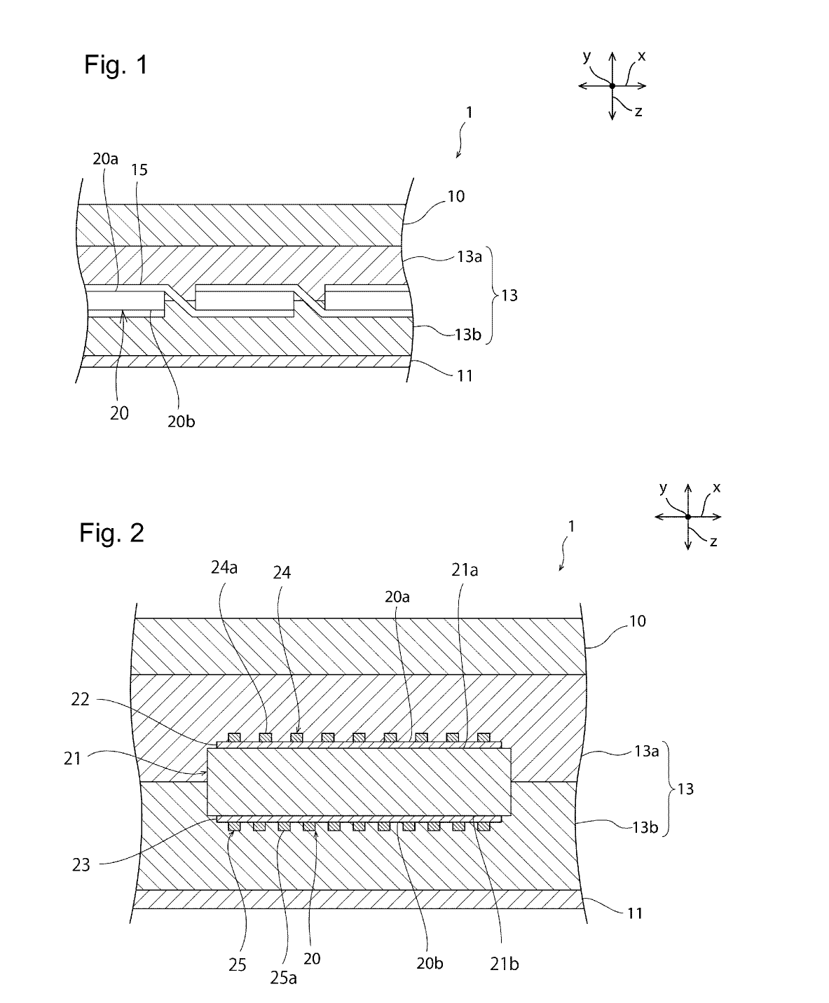

As illustrated in FIG. 1, solar cell module 1 includes solar cells 20. Specifically, solar cell module 1 includes multiple solar cells 20. Solar cells 20 are electrically connected to each other by wiring members 15.

Solar cells 20 are arranged inside sealant 13 provided between light-receiving surface member 10 and rear surface member 11. Light-receiving surface member 10 is arranged at a light-receiving surface 20a side of solar cells 20, and rear surface member 11 is arranged at a rear surface 20b side of solar cells 20. Here, a “light-receiving surface” means a surface that mainly receives light, and a “rear surface” means the other principle surface.

Light-receiving surface member 10 may be made of, for example, a glass plate, a ceramic plate, a resin plate, or the like. Rear surface member 11 may be made of, for example, a resin sheet, a resin sheet including a barrier layer made of a metal or inorganic oxide, a glass plate, a resin plate, or the like. Sealant 13 may be made of, for example, ethylene vinyl acetate (EVA), polyolefin, or the like.

Sealant 13 includes first sealant member 13a located on a light-receiving surface side with respect to solar cells 20, and second sealant member 13b located on a rear surface side with respect to solar cells 20. Second sealant member 13b located at the rear surface side with respect to solar cells 20 contains pigment, dye, or the like, which reflects at least infrared light. Alternatively, second sealant member 13b is made of a material that reflects at least infrared light. Thus, second sealant member 13b constitutes a reflection material by which light entering from the light-receiving surface side and containing infrared light is reflected toward the light-receiving surface side. The infrared light transmitted through solar cells 20 is reflected toward solar cells 20 by second sealant member 13b. Here, titanium oxide is one example of pigments that reflect infrared light.

As illustrated in FIG. 2, each solar cell 20 includes photoelectric conversion body 21. Photoelectric conversion body 21 is a member which generates carriers such as electrons and holes when receiving light. Photoelectric conversion body 21 may be made of, for example, silicon. If photoelectric conversion body 21 contains silicon, photoelectric conversion body 21 can transmit infrared light.

First transparent conductive oxide layer 22 is arranged on principle surface 21a of photoelectric conversion body 21 on the light-receiving surface side. First transparent conductive oxide layer 22 located at the light-receiving surface side of photoelectric conversion body 21 is made of indium oxide containing a metal dopant. As the metal dopant, preferably used is tungsten, tin or the like, for example. Among them, tungsten is used as the most preferable metal dopant. Hence, first transparent conductive oxide layer 22 may be preferably made of indium oxide containing tungsten (IWO). First transparent conductive oxide layer 22 may contain hydrogen or contain no hydrogen.

First transparent conductive oxide layer 22 may contain crystals. In other words, first transparent conductive oxide layer 22 may be made of a polycrystalline layer or monocrystalline layer of indium oxide containing a metal dopant.

First transparent conductive oxide layer 22 preferably has a thickness of approximately 50 nm to 200 nm, for example.

First electrode 24 is arranged on first transparent conductive oxide layer 22. First electrode 24 may be made of at least one kind of metals such for example as Ag and Cu. First electrode 24 includes first finger portions 24a arranged at certain intervals in an x axis direction. First finger portions 24a may be electrically connected to each other by a busbar portion.

Second transparent conductive oxide layer 23 is arranged on principle surface 21b of photoelectric conversion body 21 on the rear surface side. Second transparent conductive oxide layer 23 located at the rear surface side of photoelectric conversion body 21 is made of indium oxide not containing a metal dopant but containing hydrogen. Here, “not containing a metal dopant” means substantially not containing a metal dopant. Second transparent conductive oxide layer 23 may contain a metal dopant as unavoidable impurities.

If first transparent conductive oxide layer 22 contains hydrogen, it is preferable that a hydrogen concentration in second transparent conductive oxide layer 23 be higher than a hydrogen concentration in first transparent conductive oxide layer 22.

Second transparent conductive oxide layer 23 may contain crystals. In other words, second transparent conductive oxide layer 23 may be formed of a polycrystalline layer or monocrystalline layer of indium oxide not containing a metal dopant but containing hydrogen.

Second transparent conductive oxide layer 23 preferably has a thickness of approximately 50 nm to 200 nm, for example.

Second electrode 25 is arranged on second transparent conductive oxide layer 23. Second electrode 25 may be made of at least one kind of metals such for example as Ag and Cu. Second electrode 25 includes multiple second finger portions 25a arranged at certain intervals in the x axis direction. Multiple second finger portions 25a may be electrically connected to each other by a busbar portion. It is preferable that the number of second finger portions 25a be larger than that of first finger portions 24a. Each second finger portion 25a may be thicker than each first finger portion 24a. The percentage of an area of rear surface 20b occupied by second electrode 25 is preferably higher than the percentage of an area of light-receiving surface 20a occupied by first electrode 24, or is more preferably two or more times, or even more preferably five or more times the percentage of the area of light-receiving surface 20a occupied by first electrode 24.

Here, an indium oxide layer achieves a higher electric conductivity when doped with a metal dopant. Hence, one may generally conceive an idea that a first transparent conductive oxide layer on the light-receiving surface side and a second transparent conductive oxide layer on the rear surface side can be both formed of indium oxide layers containing metal dopants. However, an indium oxide layer containing a metal dopant has a lower infrared light transmittance than an indium oxide layer not containing a metal dopant. For this reason, if the second transparent conductive oxide layer is made of indium oxide containing a metal dopant, the second transparent conductive oxide layer tends to absorb infrared light transmitted through the photoelectric conversion body, and accordingly reduces a light amount of infrared light reflected by the second sealant member and then again entering the photoelectric conversion body. This results in a low utilization efficiency of infrared light.

In solar cell module 1, second transparent conductive oxide layer 23 does not contain a metal dopant. Thus, second transparent conductive oxide layer 23 has a low infrared light absorption rate. Second transparent conductive oxide layer 23 has a high infrared light transmittance. Therefore, the light amount of infrared light transmitted through solar cells 20, reflected by second sealant member 13b and then again entering solar cells 20 can be increased, and accordingly the utilization efficiency of infrared light can be enhanced.

For the purpose of restricting the absorption of infrared light at a portion other than the photoelectric conversion body, one may consider an idea that not only the second transparent conductive oxide layer but also the first transparent conductive oxide layer can be made of indium oxide not containing a metal dopant. However, in a visible wavelength range, the transmittance of an indium oxide layer not containing a metal dopant is higher than the transmittance of an indium oxide layer containing a metal dopant. For this reason, if both the first and second transparent conductive oxide layers are made of indium oxide not containing a metal dopant, visible light may be absorbed in a larger amount by the first transparent conductive oxide layer, which may result in a low utilization efficiency of visible light.

In solar cell module 1, first transparent conductive oxide layer 22 located on the light-receiving surface side with respect to photoelectric conversion bodies 21 which absorb visible light is made of the indium oxide containing the metal dopant. Thus, first transparent conductive oxide layer 22 transmits light in the visible wavelength range at a high transmittance. Consequently, in solar cell module 1, not only the utilization efficiency of infrared light but also the utilization efficiency of visible light is high. Hence, superior output characteristics can be achieved.

Moreover, in solar cell module 1, since hydrogen is added to second transparent conductive oxide layer 23 which is prone to have a low electric conductivity, the lowering of the electric conductivity of second transparent conductive oxide layer 23 may be suppressed.

As described above, having high utilization efficiencies of both visible light and infrared light, and a high electric conductivity of second transparent conductive oxide layer 23, solar cell module 1 is capable of achieving excellent output characteristics.

In order to avoid blockage of light incidence to a photoelectric conversion body, first electrode 24 is hardly formed over a large area. On the other hand, second electrode 25 does not necessarily have to transmit light because second electrode 25 is located on the rear surface side with respect to photoelectric conversion bodies 21. For this reason, for example, second electrode 25 may be made thicker than first electrode 24, so that the electric conductivity of the second electrode 25 can be improved. Instead, the number of second finger portions 25a of second electrode 25 may be made larger than the number of first finger portions 24a of first electrode 24, so that the electric conductivity of the second electrode 25 can be improved. Therefore, the output characteristics of solar cell module 1 can be further improved.

For the purpose of enhancing the electric conductivities of first and second transparent conductive oxide layers 22, 23, it is preferable that first and second transparent conductive oxide layers 22, 23 be layers containing crystals.

Hereinafter, description is provided for a method of manufacturing solar cell module 1.

First, second transparent conductive oxide layer 23 not containing a metal dopant is formed on photoelectric conversion body 21. Thereafter, first transparent conductive oxide layer 22 containing a metal dopant is formed. With this way, second transparent conductive oxide layer 23 can be inhibited from being contaminated with a metal dopant. Here, first and second transparent conductive oxide layers 22, 23 may be formed by, for example, CVD (Chemical Vapor Deposition), sputtering or the like.

It is preferable to perform a process of crystallizing first and second transparent conductive oxide layers 22, 23 after layers 22, 23 are formed. This makes it possible to improve the electric conductivities of first and second transparent conductive oxide layers 22, 23.

Next, solar cell 20 is brought into completion by forming first and second electrodes 24, 25. First and second electrodes 24, 25 may be formed by plating, CVD, sputtering, application of conductive paste, or the like.

Subsequently, light-receiving surface member 10, a resin sheet for forming first sealant member 13a, solar cells 20, a resin sheet for forming second sealant member 13b, and rear surface member 11 are stacked in this order. Then, solar cell module 1 can be brought into completion by laminating the obtained stack.

Hereinafter, other examples of preferable embodiments are explained. In the following explanation, a member having the substantially same function as that in the foregoing first embodiment is denoted by the same reference numeral, and the explanation thereof is omitted.

### Second Embodiment

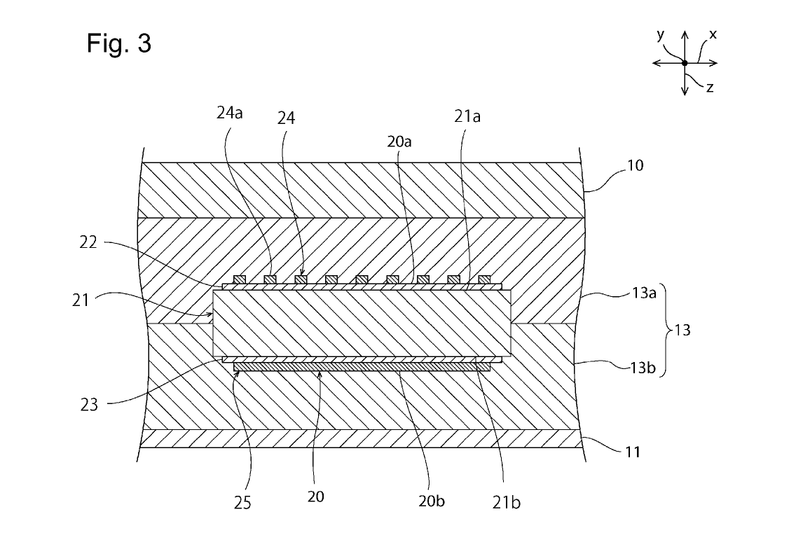

The first embodiment is described by using an example in which second electrode 25 includes multiple finger portions 25a. It should be noted that the invention is not limited to the above configuration. For example, as illustrated in FIG. 3, second electrode 25 may be formed of a sheet-shaped electrode. In this case, it is preferable that second electrode 25 be formed to cover principle surface 21b substantially entirely except for a peripheral portion of principle surface 21b. Since second electrode 25 also has a function as a reflection member to reflect infrared light, second sealant member 13b may be formed without pigment or the like added thereto, and thereby be configured to transmit infrared light.

According to the embodiments described above, it is possible to improve output characteristics of a solar cell module.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell comprising:
a photoelectric conversion body with first and second principle surfaces;
a first transparent conductive oxide layer on the first principle surface, and comprising indium oxide containing a metal dopant;
a first electrode on the first transparent conductive oxide layer;
a second transparent conductive oxide layer on the second principle surface, and comprising indium oxide not containing a metal dopant but containing hydrogen; and
a second electrode on the second transparent conductive oxide layer.

2. The solar cell according to claim 1, wherein the second transparent conductive oxide layer is thicker than the first transparent conductive oxide layer.

3. The solar cell according to claim 1, wherein each of the first and second transparent conductive oxide layers comprises crystals.

4. The solar cell according to claim 1, wherein
the first electrode includes first finger portions,
the second electrode includes second finger portions,
the number of the second finger portions is larger than the number of the first finger portions.

5. The solar cell according to claim 1, wherein the second electrode has a sheet shape.

6. The solar cell according to claim 1, wherein the first transparent conductive oxide layer comprises indium oxide containing tungsten.

7. A solar cell module comprising:
a sealant; and
a solar cell arranged inside of the sealant, wherein
the solar cell includes
a photoelectric conversion body with first and second principle surfaces,
a first transparent conductive oxide layer on the first principle surface, and comprising indium oxide containing a metal dopant,
a first electrode on the first transparent conductive oxide layer,
a second transparent conductive oxide layer on the second principle surface, and comprising indium oxide not containing a metal dopant but containing hydrogen, and
a second electrode on the second transparent conductive oxide layer; and
a reflection material that reflects more infrared light than the second principle surface to a rear surface side of the solar cell.

8. The solar cell module according to claim 7, wherein the second transparent conductive oxide layer is thicker than the first transparent conductive oxide layer.

9. The solar cell module according to claim 7, wherein each of the first and second transparent conductive oxide layers is a layer containing crystals.

10. The solar cell module according to claim 7, wherein the first transparent conductive oxide layer comprises the indium oxide containing tungsten.

11. The solar cell module according to claim 7, wherein the reflection material pertains to a portion of the sealant located on the rear surface side with respect to the second principle surface.

12. The solar cell module according to claim 7, wherein the reflection material pertains to the second electrode.

13. The solar cell module according to claim 12, wherein
the first electrode includes first finger portions,
the second electrode includes second finger portions,
the number of the second finger portions is larger than the number of the first finger portions.

14. The solar cell module according to claim 12, wherein the second electrode has a sheet shape.

15. A method of manufacturing a solar cell, comprising:
forming a second transparent conductive oxide layer on a second principle surface of a photoelectric conversion body with a first principle surface and the second principle surface, the second transparent conductive oxide layer made of indium oxide not containing a metal dopant but containing hydrogen, and forming a first transparent conductive oxide layer on the first principle surface, the first transparent conductive oxide layer made of indium oxide containing a metal dopant; and
forming a first electrode on the first transparent conductive oxide layer and forming a second electrode on the second transparent conductive oxide layer.

16. The method of manufacturing a solar cell according to claim 15, wherein the first transparent conductive oxide layer is formed after the second transparent conductive oxide layer is formed.

17. The method of manufacturing a solar cell according to claim 15, further comprising crystallizing each of the first and second transparent conductive oxide layers.
